(19) United States
(12) Patent Application Publication
(10) Pub. No.: US 2007/0298329 A1
(43) Pub. Date: Dec. 27, 2007

(54) PHOTOMASK AND METHOD FOR USING THE SAME

(76) Inventor: Chi-Ching Huang, Tainan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/309,096

(22) Filed: Jun. 22, 2006

(51) Int. Cl. G03F 1/00; G03F 9/00

(52) U.S. Cl. 430/5; 430/22

(57) ABSTRACT

The invention is directed to a photomask for a photolithography process. The photomask comprises a substrate, at least one image region and a plurality of alignment marks. The image regions are located on the substrate and at least an image center of one of the image regions non-overlap with a substrate center. The alignment marks are located on the substrate and surrounding each of the image regions. Each of the image regions is surrounded by at least four alignment marks.

### BACKGROUND OF THE INVENTION

1. Field of Invention

The present invention relates to a photomask and a method for using the same. More particularly, the present invention relates to a photomask having a plurality of alignment marks disposed around each of images thereon and a method for using the same.

2. Description of Related Art

The photolithography of the semiconductor process employs the light source irradiating a photomask and the reflection and the transmission of the incident light so as to transferring the image on the photomask onto a photo sensitive material on a wafer. Generally, one exposure process is performed with the photomask onto one corresponding die. Accordingly, the image is sequentially transferred onto each die of the wafer by using the relative movement between the photomask and the wafer. Moreover, it is necessary to performed several times of photolithography process with several photomasks to form a complete device. Therefore, before each image transferring procedure, the current process layer should be aligned to previous process layers.

Usually, before the photolithography process is performed, the alignment marks on the photomasks are aligned onto the wafer alignment marks on the wafer edge region respectively so as to place the photomask and the wafer to be at an accurate overlay position. Then, an exposure process is performed to transfer image of the photomask onto each die of the wafer. Currently, the conventional photomask only has four alignment marks disposed at four corners of the photomask respectively.

Nevertheless, when the image center and the photomask center do not overlap with each other, the phenomenon such as image shifting, image rotation or abnormal image magnification happens. Furthermore, during the exposure process, the photomask is at a heated-cooled down cycle. Therefore, when the image is sequentially transferred onto each die, the aforementioned phenomenon is getting seriously. Hence, the quality of the image transferring between the dies on the same wafer and the overlay between the current process layer and the previous process layer are degraded. Accordingly, the wafer is discarded and the yield is low.

### SUMMARY OF THE INVENTION

Accordingly, at least one objective of the present invention is to provide a photomask capable of accurately aligning the photomask onto the wafer in a photolithography process.

At least another objective of the present invention is to provide a photomask for a photolithography process capable of preventing the wafer from being discarded and improving the yield of the photolithography process.

To achieve these and other advantages and in accordance with the purpose of the invention, as embodied and broadly described herein, the invention provides a photomask for a photolithography process. The photomask comprises a substrate, at least one image region and a plurality of alignment marks. The image regions are located on the substrate and at least an image center of one of the image regions non-overlap with a substrate center. The alignment marks are located on the substrate and surrounding each of the image regions. Each of the image regions is surrounded by at least four alignment marks.

According to the photomask in one embodiment of the present invention, each side of each of the image regions has at least one of the alignment marks disposed aside.

According to the photomask in one embodiment of the present invention, each corner of each of the image regions has at least one of the alignment marks disposed aside.

According to the photomask in one embodiment of the present invention, the sizes of the image regions are as same as each other and the shapes of the image regions are as same as each other.

According to the photomask in one embodiment of the present invention, at least a shape of one of the image regions is different from those of the other image regions.

According to the photomask in one embodiment of the present invention, at least a size of one of the image regions is different from those of the other image regions.

According to the photomask in one embodiment of the present invention, the shapes of the alignment marks are selected from a group consisting of cruciform shape, triangle shape, rectangle shape and polygon.

According to the photomask in one embodiment of the present invention, the image center is an intersection point of the diagonal lines of the image region.

According to the photomask in one embodiment of the present invention, the substrate center is an intersection point of the diagonal line of the substrate.

The present invention also provides an exposure method for a wafer having a photo sensitive material layer formed thereon. The exposure method comprises providing a photomask. The photomask comprises a substrate, at least one image region and a plurality of alignment marks. The image regions are located on the substrate and at least an image center of one of the image regions non-overlap with a substrate center. The alignment marks are located on the substrate and surrounding each of the image regions. Each of the image regions is surrounded by at least four alignment marks. Then, an exposure image region is selected from the image regions. The alignment marks around the exposure image region are aligned onto a plurality of wafer alignment mark disposed at an edge of the wafer respectively. The exposure image region is transferred onto the photo sensitive material layer on the wafer.

According to the exposure method in one embodiment of the present invention, each side of each of the image regions has at least one of the alignment marks disposed aside.

According to the exposure method in one embodiment of the present invention, each corner of each of the image regions has at least one of the alignment marks disposed aside.

According to the exposure method in one embodiment of the present invention, the sizes of the image regions are as same as each other and the shapes of the image regions are as same as each other.

According to the exposure method in one embodiment of the present invention, at least a shape of one of the image regions is different from those of the other image regions.

According to the exposure method in one embodiment of the present invention, at least a size of one of the image regions is different from those of the other image regions.

According to the exposure method in one embodiment of the present invention, the shapes of the alignment marks are selected from a group consisting of cruciform shape, triangle shape, rectangle shape and polygon.

According to the exposure method in one embodiment of the present invention, the image center is an intersection point of the diagonal lines of the image region.

According to the exposure method in one embodiment of the present invention, the substrate center is an intersection point of the diagonal line of the substrate.

According to the exposure method in one embodiment of the present invention, the exposure image region comprises at least one of the image regions.

According to the exposure method in one embodiment of the present invention, the photo sensitive material layer is selected from a group consisting of a positive photoresist, a negative photoresist or other photo sensitive material.

The arrangement and the number of the alignment marks are designed according to the size and the number of the image regions so that the phenomenon such as image shifting, image rotation and image abnormal magnification can be improved. Hence, the wafer can be prevented from being discarded and the yield of the photolithography process can be increased.

In order to make the aforementioned and other objects, features and advantages of the present invention comprehensible, a preferred embodiment accompanied with figures is described in detail below.

### BRIEF DESCRIPTION OF THE DRAWINGS

FIG. 1 is a top view of a photomask structure according to one embodiment of the present invention.

FIG. 2 is a top view of a photomask structure according to another embodiment of the present invention.

FIG. 3 is a top view of a photomask structure according to the other embodiment of the present invention.

FIG. 4 is a flow chart illustrating an exposure method according to one embodiment of the present invention.

### DESCRIPTION OF EMBODIMENTS

To solve the problems of the exposure image shifting, exposure image rotating and exposure image abnormally magnification due to the exposure image region non-overlap with the mask center, the present invention provides a photomask design in which more than one alignment mark is disposed aside each of the image regions. Therefore, the relative position between the photomask and the wafer can be adjusted by aligning the alignment marks around the selected image region onto the wafer alignment marks on the wafer respectively.

As shown in FIG. 1, the photomask 100 can, for example, comprise a substrate 102, an image region 110 and several alignment marks 120. The substrate 102 can be, for example, a glass substrate, a plastic substrate or a proper substrate made of transparent material. The image region 110 is located on the substrate 102 and the center 112 of the image region 110 is non-overlap with the substrate center 104 of the substrate 102. The image center 112 is the intersection point of the diagonal lines of the image region 110 and the substrate center 104 is the intersection point of the diagonal lines of the substrate 102. The image region 110 can be, for example, a pattern made of opaque material layer or translucent material layer or can be, for example, formed by etching the substrate 102. The alignment marks 120 are disposed on the substrate 102 and surrounding the image region 110. Furthermore, one image region 110 is surrounded by at least four alignment marks 120. The method for forming the alignment marks can, for example, comprise forming trenches in the substrate 102 by etching the substrate 102.

In this embodiment, the photomask having one image region and the image center non-overlap with the substrate center are used to describe the present invention. However, the shape and the size of the image region on the photomask of the present invention are not limited to this embodiment. Moreover, the shapes of the alignment marks 120 are not limited to the rectangle shape. That is, the shapes of the alignment marks 120 can be selected from a group consisting of cruciform shape, triangle shape and polygon. Furthermore, the number and the positions of alignment marks 120 are not limited to this embodiment. On the other words, at least one alignment mark 120 is disposed aside one side of the image region 110 or at least one alignment mark 120 is disposed near each of the corners of the image region 110.

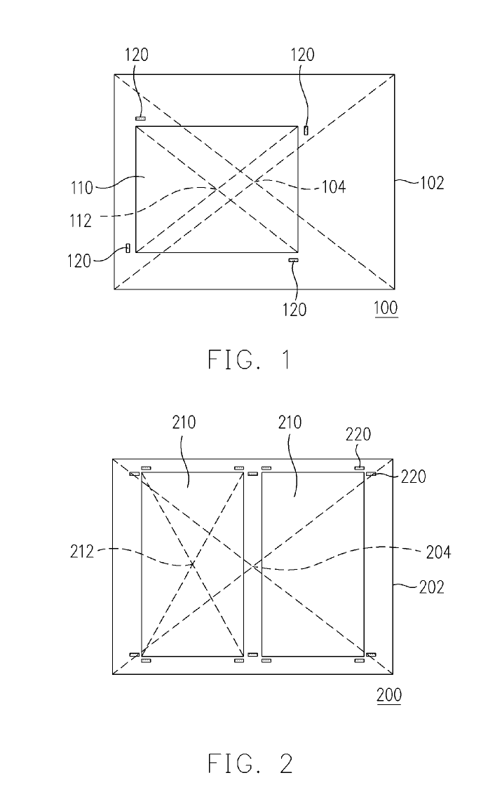

FIG. 2 is a top view of a photomask structure according to another embodiment of the present invention.

As shown in FIG. 2, the photomask 200 can, for example, comprise a substrate 202, two image regions 210 and several alignment marks 220. The substrate 202 can be, for example, a glass substrate, a plastic substrate or a proper substrate made of transparent material. The image regions 210 are located on the substrate 202 and at least one of the image centers of the image regions is non-overlap with the substrate center 204 of the substrate 202. The image center 212 is the intersection point of the diagonal lines of the image region 210 and the substrate center 204 is the intersection point of the diagonal lines of the substrate 202. The sizes of the image regions 210 are as same as each other and the shapes of the image regions 210 are as same as each other. The image regions 210 can be, for example, patterns made of opaque material layer or translucent material layer or can be, for example, formed by etching the substrate 202. The alignment marks 220 are disposed on the substrate 202 and surrounding each of the image regions 210 respectively. Furthermore, each corner of each of the image regions 210 has two alignment marks 220 disposed aside and two image regions 210 can share the same alignment marks 220. The method for forming the alignment marks 220 can, for example, comprise forming trenches in the substrate 202 by etching the substrate 202.

In this embodiment, the photomask having two image regions with identical shapes and identical sizes and none of the image centers of the image regions non-overlap with the substrate center are used to describe the present invention. The aforementioned photomask having two image regions with identical shapes and identical sizes is the alleged symmetric photomask. However, the number, the shapes and the sizes of the image regions on the photomask of the present invention are not limited to this embodiment. Moreover, the shapes of the alignment marks 220 are not limited to the rectangle shape. That is, the shapes of the alignment marks 220 can be selected from a group consisting of cruciform shape, triangle shape and polygon. Furthermore, the number and the positions of alignment marks 220 are not limited to this embodiment. On the other words, at least one alignment mark 220 is disposed aside one side of each of the image regions 210 or at least one alignment mark 220 is disposed near each of the corners of each of the image regions 210.

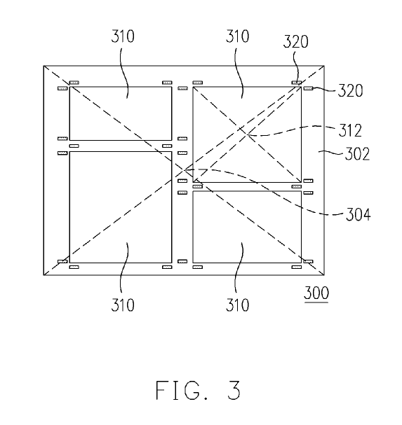

FIG. 3 is a top view of a photomask structure according to the other embodiment of the present invention.

As shown in FIG. 3, the photomask 300 can, for example, comprise a substrate 302, four image regions 310 and several alignment marks 320. The substrate 302 can be, for example, a glass substrate, a plastic substrate or a proper substrate made of transparent material. The image regions 310 are located on the substrate 302 and at least one of the image centers of the image regions is non-overlap with the substrate center 304 of the substrate 302. The image center 312 is the intersection point of the diagonal lines of the image region 310 and the substrate center 304 is the intersection point of the diagonal lines of the substrate 302. The sizes of the image regions 310 can be different from each other and the shapes of the image regions 210 can be different from each other as well. The image regions 310 can be, for example, patterns made of opaque material layer or translucent material layer or can be, for example, formed by etching the substrate 302. The alignment marks 320 are disposed on the substrate 302 and surrounding each of the image regions 310 respectively. Furthermore, each corner of each of the image regions 310 has two alignment marks 320 disposed aside and any two adjacent image regions 310 can share the same alignment marks 320. The method for forming the alignment marks 320 can, for example, comprise forming trenches in the substrate 302 by etching the substrate 302.

In this embodiment, the photomask having at least one image region with the shape or the size different from those of other image regions and none of the image centers of the image regions non-overlap with the substrate center are used to describe the present invention. The aforementioned photomask having at least one image region with the shape or the size different from those of other image regions is the alleged asymmetric photomask. Nevertheless, the number, the shapes and the sizes of the image regions on the photomask of the present invention are not limited to this embodiment. Moreover, the shapes of the alignment marks 320 are not limited to the rectangle shape. That is, the shapes of the alignment marks 320 can be selected from a group consisting of cruciform shape, triangle shape and polygon. Furthermore, the number and the positions of alignment marks 320 are not limited to this embodiment. On the other words, at least one alignment mark 320 is disposed aside one side of each of the image regions 310 or at least one alignment mark 320 is disposed near each of the corners of each of the image regions 310.

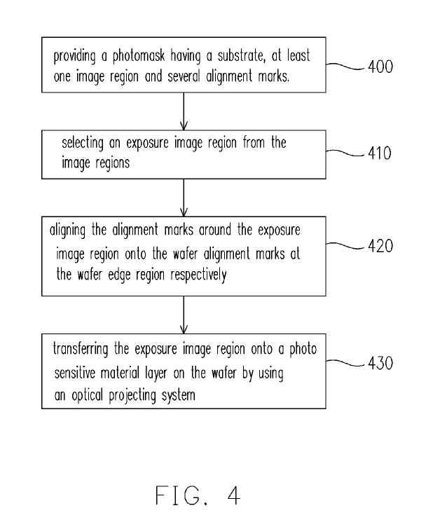

FIG. 4 is a flow chart illustrating an exposure method according to one embodiment of the present invention.

In the step 400, a photomask is provided. The photomask comprises a substrate having at least one image region and several alignment marks formed thereon. The image regions are located on the substrate and at least one of the image centers of the image regions is non-overlap with the substrate center of the substrate. The alignment marks are located on the substrate and surrounding each of the image regions respectively. Furthermore, at least four alignment marks surround one image region. The arrangements of all elements on the photomask and the method for forming the elements on the photomask can be accomplished according to one of the embodiments stated from FIG. 2 to FIG. 4 and, accordingly, are not detailed described herein.

In the step 410, at least one image region selected from the image regions on the photomask is used as an exposure image region to be transferred in this exposure procedure. That is, for one exposure process, more than one image region can be combined to be an exposure region as the exposure image region stated above. Further, the image region can be disposed on any position on the photomask.

Then, in the step 420, the alignment marks around the exposure image region on the photomask are correspondingly aligned onto several wafer alignment marks on the edge of a wafer respectively.

Moreover, in the step 430, the pattern in the exposure image region is transferred onto a photo sensitive material layer on the wafer by using a optical projecting system. The optical projecting system comprises members such as the light source, the condenser lens and the objective lens. In addition, the photo sensitive material layer can be, for example, made of the positive photoresist, the negative photoresist or other proper photo sensitive material.

Altogether, in the present invention, more than one alignment mark is disposed aside each side of each image region or aside each corner of each image region. Moreover, the aforementioned design of the alignment mark around each of the image regions can be applied to various photomask with image center non-overlap with the substrate center no matter the photomask possesses only one image region or several image regions and no matter the photomask is a symmetric photomask or an asymmetric photomask. Therefore, before the photolithography process is performed, the relative position between the photomask and the wafer can be adjusted by aligning the alignment marks around the selected exposure image region onto the wafer alignment marks on the wafer respectively. Accordingly, during the continuously performed exposure process, the exposure image shifting, rotating and abnormal image magnification due to high temperature can be improved. Hence, the image transferring qualities of the dies on the same wafer is uniform and the overlay between the current process layer and the previous process layer is improved. Accordingly, the wafer can be prevented from being discarded and the yield of the photolithography process is improved.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A photomask for a photolithography process, comprising:
a substrate;
at least an image region located on the substrate, wherein at least an image center of one of the image regions non-overlap with a substrate center; and
a plurality of alignment marks located on the substrate and surrounding each of the image regions, wherein each of the image regions is surrounded by at least four alignment marks.

2. The photomask of claim 1, wherein each side of each of the image regions has at least one of the alignment marks disposed aside.

3. The photomask of claim 1, wherein each corner of each of the image regions has at least one of the alignment marks disposed aside.

4. The photomask of claim 1, wherein the sizes of the image regions are as same as each other and the shapes of the image regions are as same as each other.

5. The photomask of claim 1, wherein at least a shape of one of the image regions is different from those of the other image regions.

6. The photomask of claim 1, wherein at least a size of one of the image regions is different from those of the other image regions.

7. The photomask of claim 1, wherein the shapes of the alignment marks are selected from a group consisting of cruciform shape, triangle shape, rectangle shape and polygon.

8. The photomask of claim 1, wherein the image center is an intersection point of the diagonal lines of the image region.

9. The photomask of claim 1, wherein the substrate center is an intersection point of the diagonal line of the substrate.

10. An exposure method for a wafer having a photo sensitive material layer formed thereon, the exposure method comprising:
providing a photomask, wherein the photomask comprises:
a substrate;
at least an image region located on the substrate, wherein at least an image center of one of the image regions dose non-overlap with a substrate center; and
a plurality of alignment marks located on the substrate and surrounding each of the image regions, wherein each of the image regions is surrounded by at least four alignment marks;
selecting an exposure image region from the image regions;
aligning the alignment marks around the exposure image region onto a plurality of wafer alignment mark disposed at an edge of the wafer respectively; and
transferring the exposure image region onto the photo sensitive material layer on the wafer.

11. The exposure method of claim 10, wherein each side of each of the image regions has at least one of the alignment marks disposed aside.

12. The exposure method of claim 10, wherein each corner of each of the image regions has at least one of the alignment marks disposed aside.

13. The exposure method of claim 10, wherein the sizes of the image regions are as same as each other and the shapes of the image regions are as same as each other.

14. The exposure method of claim 10, wherein at least a shape of one of the image regions is different from those of the other image regions.

15. The exposure method of claim 10, wherein at least a size of one of the image regions is different from those of the other image regions.

16. The exposure method of claim 10, wherein the shapes of the alignment marks are selected from a group consisting of cruciform shape, triangle shape, rectangle shape and polygon.

17. The exposure method of claim 10, wherein the image center is an intersection point of the diagonal lines of the image region.

18. The exposure method of claim 10, wherein the substrate center is an intersection point of the diagonal line of the substrate.

19. The exposure method of claim 10, wherein the exposure image region comprises at least one of the image regions.

20. The exposure method of claim 10, wherein the photo sensitive material layer is selected from a group consisting of a positive photoresist, a negative photoresist or other photo sensitive material.
